(19) United States
(12) Patent Application Publication
(10) Pub. No.: US 2005/0214978 A1
(43) Pub. Date: Sep. 29, 2005

(54) Lower profile flexible substrate package for electronic components

(76) Inventors: Brian Taggart, Phoenix, AZ (US); Robert M. Nickerson, Chandler, AZ (US); Ronald I. Spreitzer, Phoenix, AZ (US)

Correspondence Address: TROP PRUNER & HU, PC, 8554 KATY FREEWAY, SUITE 100, HOUSTON, TX, 77024, US

(21) Appl. No.: 10/807,830

(22) Filed: Mar. 24, 2004

(51) Int. Cl. H01L 21/20

(52) U.S. Cl. 438/113

(57) ABSTRACT

Buildup layers may be formed over a flexible substrate. A suitable cavity may be formed in the buildup layers and a silicon die may be positioned over the flexible substrate on a die attach formed within the cavity. As a result, a lower profile flexible substrate package is possible.

### BACKGROUND

This invention relates generally to flexible substrate packages for electronic components.

Flexible substrate packages, such as polyamide packages, have a flexible substrate sometimes called a flex substrate. Thus, the base cavity is flexible and this can be used for a number of applications, including folded packages.

Polyamide packages generally have an interconnect structure formed within the polyamide substrate. A silicon die is positioned over the polyamide substrate, interconnections are made, for example by wire bonding, and the structure over the polyamide substrate is mold encapsulated. While these structures are advantageously flexible, their vertical profile may be too high for some applications.

Thus, there is a need for lower profile flexible substrate packaging.

### BRIEF DESCRIPTION OF THE DRAWINGS

FIG. 1 is an enlarged, cross-sectional view of one embodiment of the present invention.

### DETAILED DESCRIPTION

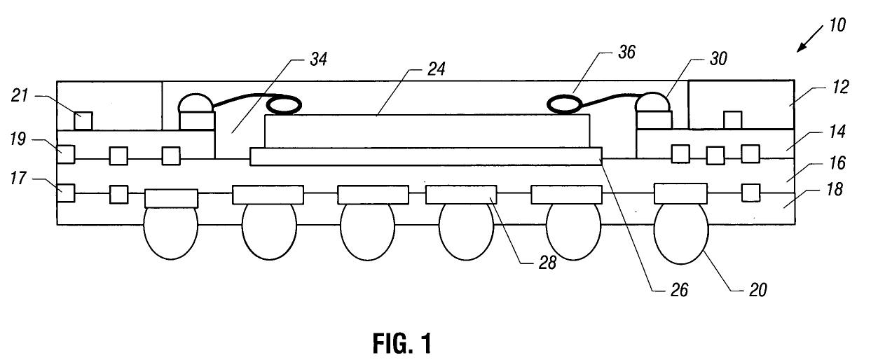

Referring to FIG. 1, a flexible substrate packaged semiconductor integrated circuit 10 includes at least one silicon die 24 covered by an encapsulant 36. A flexible substrate core 16, made of polyamide in one embodiment, is coupled to lands 28 on its lower surface in one embodiment. The lands 28 may also be located outside the die shadow area in another embodiment. A series of openings in a covering layer 18 provide for the attachment of solder balls 20 to the lands 28.

The lands 28 may be electrically coupled through an interconnection layer 17 (over the core 16), which in turn electrically couples through vias (not shown) to interconnection layers 19 and 21, contained in buildup layers 12 and 14. Thus, the interconnection structure, made up of the interconnection layers 17, 19, and 21 and the associated vias, may be formed within buildup layers 12 and 14, as opposed to forming them within the substrate core 16. The buildup layers 14 and 12 may be stepped in one embodiment of the present invention so that a cavity 34 is defined which opens up progressively in the stepped fashion.

The integrated circuit die 24 may be attached by a die attach 26 to the polyamide substrate core 16. Thus, the die 24 sits within the cavity 34 within the package 10, defined by the buildup layers 14 and 12. This configuration may be thermally efficient in some embodiments. In addition, because the interconnection layers 17, 19, and 21 are at least partially removed from the core 16, a lower profile package may be achieved.

While an embodiment is shown with two buildup layers 12 and 14, more buildup layers may be utilized in other embodiments.

In some embodiments, the buildup layers 12 and 14 may be adapted to the thickness of the die 14 so that the upper surface of the die 24 and the upper buildup layer 12 are substantially coplanar. However, in the embodiment illustrated, with a down set configuration between the upper surface of the buildup layer 12 and the upper surface of the silicon die 24, room is provided for wire bonds from contacts 30 on the buildup layer 14 to contacts 32 on the die 24. In another embodiment, flip chip bonding may be provided between the die 24 and the interconnect layers. Also, two dice may be included, with the dice coupled by flip or wire bond interconnections, as two examples.

Thus, in a structure with three interconnection layers 17, 19, and 21, the silicon die 24 may be down set into a cavity 34 providing a thermally efficient lower profile arrangement. The electrical interconnections may be provided through three separate interconnection layers 17, 19, and 21 formed in buildup layers 12 and 14. In some embodiments, a folded package may be utilized to take advantage of the flexible substrate core 16.

The package 10 may be formed using standard flexible substrate manufacturing steps. When manufacturing a three-plus metal layer flex substrate, a route or punch cavity is formed in the buildup layers 12 and 14. This routing of the cavity can be done in panel or reel-to-reel format, as two examples. The buildup layers are then laminated with the cavity. The top layer may be patterned and then a solder mask may be applied. Thereafter, the typical back end steps, including rinse and bake, may be accomplished.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. At least one packaged integrated circuit comprising:
a semiconductor die;
a flexible substrate, said die attached to said substrate;
at least two buildup layers formed over said substrate, a cavity formed in said buildup layers, and said die mounted in said cavity; and
a folded package.

2. The circuit of claim 1 including lands below said flexible substrate, said lands coupled to solder balls.

3. The circuit of claim 1 wherein said flexible substrate is formed of polyamide.

4. The circuit of claim 1 wherein said cavity is stepped.

5. The circuit of claim 4 including an interconnection layer between said buildup layers.

6. The circuit of claim 5 including an interconnection layer between one of said buildup layers and said flexible substrate.

7. The circuit of claim 6 including wire bonds from one of said interconnection layers to said die.

8. The circuit of claim 7 including a die attach between said cavity and said die.

9. The circuit of claim 1 wherein the upper surface of the upper buildup layer is higher than the upper surface of said die.

10. (canceled)

11. A method comprising:
securing a semiconductor die within a cavity in a folded flexible package.

12. The method of claim 11 including securing said die in a stepped cavity.

13. The method of claim 11 including securing said die in a cavity formed by at least two buildup layers.

14. The method of claim 13 including providing interconnection layers between said buildup layers.

15. The method of claim 14 including providing an interconnection layer between a buildup layer and a flexible substrate.

16. The method of claim 11 including packaging said die at a level in said cavity below the upper surface of said cavity.

17. The method of claim 16 including wire bonding from said package to said die.

18. The method of claim 11 including forming a flexible substrate of polyamide in said package.

19. (canceled)

20. A package comprising:
a flexible substrate;
a layer over said substrate, said layer having a cavity formed therein to receive a die; and
wherein said package is a folded package.

21. The package of claim 20 wherein said layer is formed of at least two buildup layers.

22. The package of claim 21 wherein said cavity is stepped.

23. The package of claim 20 including solder balls coupled thereto.

24. The package of claim 20 wherein said flexible substrate includes polyamide.

25. The package of claim 21 including an interconnection layer between said buildup layers.

26. The package of claim 25 including a pair of buildup layers over said flexible substrate.

27. The package of claim 25 including an interconnection layer between said substrate and one of said buildup layers.

28. The package of claim 20 including a die attach in said cavity.

29. (canceled)
